(19) United States
(12) Patent Application Publication
(10) Pub. No.: US 2026/0114245 A1
(43) Pub. Date: Apr. 23, 2026

(54) METHODS OF FORMING SEMICONDUCTOR STRUCTURES

(71) Applicant: Semiconductor Manufacturing International (Shanghai) Corporation, Shanghai (CN)

(72) Inventor: Jisong JIN, Shanghai (CN)

(21) Appl. No.: 19/359,226

(22) Filed: Oct. 15, 2025

(30) Foreign Application Priority Data
Oct. 18, 2024 (CN) 202411465881.4

(51) Int. Cl. H01L 21/033; H01L 21/311; H01L 21/3115; H10B 10/00

(52) U.S. Cl. CPC H10P 76/4085; H10B 10/12; H10P 30/40; H10P 50/283; H10P 50/73; H10P 76/405; H10B 10/18

(57) ABSTRACT

A method for forming semiconductor structures includes providing a base including a first area and second area; patterning a first core material layer and forming first core layers; forming first spacers; forming a first protective layer over a second core material layer in the second area; patterning the second core material layer using the first protective layer and the first spacers as a mask and forming second core layers; forming a second spacers; removing the second core layers in the first area and part of the second core layers in the second area; patterning a target material layer using the second spacers and remaining second core layers as a mask; and forming first target structures and second target structures. Pitch of adjacent first target structures is smaller than or equal to that of adjacent second target structures. Both SAQP and SALELE are implemented in the formation process over the base.

### CROSS-REFERENCE TO RELATED APPLICATION

This application claims the priority of Chinese Patent Application No. 202411465881.4, filed on Oct. 18, 2024, the content of which is incorporated herein by reference in its entirety.

### TECHNICAL FIELD

The present disclosure generally relates to the field of semiconductor manufacturing and, more particularly, relates to a method of forming a semiconductor structure.

### BACKGROUND

With the rapid advance of semiconductor manufacturing technologies, semiconductor devices are developing towards higher component density and higher integration. Photolithography technology is a commonly used patterning method and the most critical production technology in semiconductor manufacturing processes. Along with continuous reduction of pattern critical dimension (CD) and pitch, self-aligned double patterning (SADP) can no longer meet current process requirements, and self-aligned quadruple patterning (SAQP) method comes into being. Generally, the minimum pitch that SADP can form with the deep ultraviolet (DUV) technology is about half of the pitch limit of 76 nm for a single DUV exposure, which is a pitch of 38 nm. As such, the limit of SAQP with the DUV technology is a pitch of 19 nm. When a good yield is ensured, the general SADP limit is around 40 nm, and the SAQP limit is around 24 nm. In the back-end process, the SADP or SAQP process is often not used to form metal patterns, while self-aligned litho-etch litho-etch or spacer assisted litho-etch litho-etch (SALELE) is often used. SALELE has the advantage of more design freedom than SADP, but the metal pitch limit is similar to SADP, and the minimum pitch can only be about 40 nm.

However, as the size of transistors and chips shrinks, the back-end metal pitch also needs to reach a value of smaller than 40 nm to 30 nm or even a smaller pitch. The traditional SAQP method can achieve smaller pitches, but like SADP, it has major limitations in metal line layout design. Metal line layout generally needs to take into account both smaller pitches and large pitches on the same chip, as well as design freedom such as freely placed metal line positions, which is difficult to achieve using purely the SAQP process. However, in the absence of extreme ultraviolet (EUV) exposure processing, it is relatively difficult to achieve both pitch reduction and design freedom through the SAQP process that only uses the DUV lithography. It also has great limitations on production of chips with more advanced processes.

The disclosed structures and methods are directed to at least partially alleviating one or more problems set forth above and to solving other problems in the art.

### SUMMARY

One aspect of the present disclosure provides a method for forming a semiconductor structure. The method includes providing a base that includes a substrate and a target material layer on the substrate, forming a second core material layer over the base, and forming a first core material layer over the second core material layer, wherein the base includes a first area and a second area; patterning the first core material layer and forming first core layers separately in the first area, wherein the first core layers extend along a first direction and are arranged in parallel along a second direction, the first core layers have two adjacent first sub-core layers and a second sub-core layer arranged in an alternating manner, a width of the second sub-core layer is greater than a width of the first sub-core layer, and the first direction is perpendicular to the second direction; forming first spacers covering sidewalls of the first core layers, wherein first spacers of opposite sidewalls of adjacent first sub-core layers are in contact with each other to form an integrated structure; removing the first core layers; forming a first protective layer over the second core material layer in the second area, wherein the first protective layer is formed with separate first protective layer openings extending along the first direction and arranged in parallel along the second direction; patterning the second core material layer using the first protective layer and the first spacers as a mask, and forming second core layers; removing the first protective layer and the first spacers; forming second spacers that cover sidewalls of the second core layers; removing second core layers in the first area and part of the second core layers in the second area; and patterning the target material layer using the second spacers and remaining second core layers as a mask, and forming first target structures in the first area and second target structures in the second area, wherein first target structures corresponding to intervals between adjacent first sub-core layers and second sub-core layers are first sub-target structures, first target structures between adjacent first sub-target structures are second sub-target structures, both the first target structures and the second target structures extend along the first direction, and a pitch of adjacent first target structures is smaller than or equal to a pitch of adjacent second target structures.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 to FIG. 23 illustrate schematic structural diagrams corresponding to steps in methods for forming a semiconductor structure according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

Embodiments of the present disclosure provide a method of forming a semiconductor structure. The method improves design freedom in patterning processes.

The method includes providing a base that includes a substrate and a target material layer located on the substrate, forming a second core material layer over the base, and forming a first core material layer over the second core material layer, wherein the base includes a first area and a second area; patterning the first core material layer and forming first core layers separately in the first area, wherein the first core layers extend along a first direction and are arranged in parallel along a second direction, the first core layers have two adjacent first sub-core layers and one second sub-core layer arranged in an alternating manner along the second direction, the width of the second sub-core layer is greater than the width of the first sub-core layer, and the first direction is perpendicular to the second direction; forming first spacers covering the sidewalls of the first core layers, wherein first spacers of the opposite sidewalls of adjacent first sub-core layers are in contact with each other to form an integrated structure; removing the first core layers; forming a first protective layer over the second core material layer in the second area, wherein the first protective layer is formed with separate first protective layer openings extending along the first direction and arranged in parallel along the second direction; patterning the second core material layer using the first protective layer and the first spacers as a mask, and forming the second core layers; removing the first protective layer and first spacers; forming second spacers that cover the sidewalls of the second core layers; removing the second core layers in the first area and part of the second core layers in the second area; patterning the target material layer using the second spacers and the remaining second core layers as a mask, and forming first target structures in the first area and second target structures in the second area, wherein first target structures corresponding to intervals between adjacent first sub-core layers and the second sub-core layers are the first sub-target structure, first target structures between adjacent first sub-target structures are second sub-target structures, both the first target structures and the second target structures extend along the first direction, and the pitch of adjacent first target structures is smaller than or equal to the pitch of adjacent second target structures.

Compared with existing technologies, technical solutions of embodiments of the present disclosure have the following advantages:

In the formation method provided by embodiments of the present disclosure, for the first area, the first core layers show that two adjacent first sub-core layers and one second sub-core layer are configured in an alternating arrangement. The width of the second sub-core layer is greater than the width of the first sub-core layer. Two adjacent first sub-core layers and one second sub-core layer are taken as a cycle. First spacers of the opposite sidewalls of adjacent first sub-core layers are in contact with each other to form an integrated structure. At this time, in a cycle, two first spacers are formed between a first spacer of the integrated structure and the second sub-core layer. The first spacers are used as a mask to pattern the second core material layer in the first area to form a second core layer. Second spacers that cover the sidewalls of the second core layers are formed. At this time, in a cycle, five second spacers are formed between the first spacer of the integrated structure and the second sub-core layer. The second spacers are used as a mask to pattern the target material layer using the SAQP process. The SAQP process may be used to form the first target structures with a smaller pitch. Further, the first spacer of the integrated structure and the second sub-core layer correspondingly form a first sub-target structure with a larger width in the target material layer. The four intervals between five second spacers correspondingly form four second sub-target structures with a smaller width in the target material layer. A unit is formed that includes two first sub-target structures with larger width and four second sub-target structures with smaller width. It helps adjust the number of the first target structures formed by the SAQP process and obtain units that meet process requirements. For the second area, a first protective layer over the second core material layer in the second area is formed. The first protective layer is formed with separate first protective layer openings extending along the first direction and arranged in parallel along the second direction. The second core material layer is patterned using the first protective layer as a mask. The second core layers are formed. Second spacers are formed that cover the sidewalls of the second core layers. Part of the second core layers in the second area is removed and part of the second core layers in the second area is retained. The second spacers and the remaining second core layers are used as a mask to pattern the target material layer, and second target structures with a larger pitch are formed through the SALELE process. As such, embodiments of the present disclosure may better integrate the SAQP process and the SALELE process. Both the first target structures with a smaller pitch and the second target structures with a larger pitch are formed over the same base. It is conducive to meeting more semiconductor process needs through process integration and improving design freedom in patterning processes.

As mentioned in the background section, the SALELE process is a common solution in back-end patterning. The process has two core values in patterning. The first value is the spacing between metal lines defined by two lithographies is determined by the thickness of the spacer during the process. The spacer is usually formed by an atomic layer deposition (ALD) process with very high uniformity. As such, the overlay of two lithographies does not cause a change of spacing between two adjacent metal lines. It also makes the spacing between metal lines very uniform and fixed, and opens a large process window for reliability tests such as time dependent dielectric breakdown (TDDB) and breakdown voltage (VBD). The second value is that the tip to tip of the metal lines defined by two lithographies may be formed very small by using cuts of patterning produced by other masks. Further, a cut corresponding to the first lithography and a cut corresponding to the second lithography may not interfere with each other. This is also called a self-aligned block process in the industry.

The above two advantages are the reason that SALELE not only balances the process difficulty at the back-end patterning, but also provides great design freedom. The SALELE process also has various similar solutions, such as that shown in CN111640668B and process solutions disclosed in US10991596B2.

In general, the minimum pitch created by immersion DUV (ArFi) in a single photolithography is about 80 nm. Thus, SALELE may use DUV equipment to achieve a minimum pitch of 38 nm to 40 nm, while more advanced chips require smaller pitches, such as 32 nm, 28 nm, 24 nm, etc.

With the traditional fin patterning, when a pitch reaches about 30 nm, the SAQP process may be used. Because SADP may only make a fin pattern with a minimum pitch of 38 nm, SADP needs to be repeated to become SAQP. The SAQP process may well meet the needs of fin patterning. Because fin patterns are relatively regular, the fin pitches in an area of a chip are generally fixed and regular, and the difference between areas is not very large. However, the SAQP solution has great limitations in the back-end process where metal lines have a high degree of freedom. For example, when metal patterns of SRAM are formed, metal lines formed by patterning are difficult to match patterns of the first metal layer of the traditional SRAM. Further, the width of metal lines formed by SAQP is relatively fixed, which also makes designs of other bypass circuits more difficult.

As such, currently for back-end patterning in semiconductor structures of the same area, it is difficult to achieve both smaller pitch and design freedom, meet more requirements of semiconductor processes, and improve design freedom in patterning processes correspondingly.

In order to solve the above technical problems, embodiments of the present disclosure provide a method for forming a semiconductor structure. The method includes providing a base including a substrate and a target material layer over the substrate, forming a second core material layer over the substrate, and forming a first core material layer over the second core material layer, wherein the base includes a first area and a second area; patterning the first core material layer, and forming first core layers separately in the first area, wherein the first core layers extend along a first direction and are arranged in parallel along a second direction, multiple first core layers are arranged with two adjacent first sub-core layers and one second sub-core layer in an alternating arrangement along the second direction, the width of the second sub-core layer is greater than the width of the first sub-core layer, and the first direction is perpendicular to the second direction; forming first spacers covering the sidewalls of the first core layers, wherein first spacers of the opposite sidewalls of adjacent first sub-core layers are in contact to form an integrated structure; removing the first core layers; forming a first protective layer over the second core material layer in the second area, wherein the first protective layer is formed with separate first protective layer openings extending along the first direction and arranged in parallel along the second direction; patterning the second core material layer using the first protective layer and the first spacers as a mask and forming second core layers; removing the first protective layer and the first spacers; forming second spacers covering the sidewalls of the second core layers; removing the second core layers in the first area and part of the second core layers in the second area; and patterning the target material layer using the second spacers and the remaining second core layers as a mask and forming first target structures in the first area and second target structures in the second area, wherein first target structures corresponding to the intervals between adjacent first sub-core layers and corresponding to the second sub-core layers are first sub-target structures, first target structures between adjacent first sub-target structures are second sub-target structures, the first target structure and second target structure both extend along the first direction, and the pitch of adjacent first target structures is smaller than or equal to the pitch of adjacent second target structures.

In some embodiments, for the first area, the first core layers are configured with two adjacent first sub-core layers and one second sub-core layer in an alternating arrangement. The width of the second sub-core layer is greater than the width of the first sub-core layer. Two adjacent first sub-core layers and one second sub-core layer are used as a cycle. First spacers of the opposite sidewalls of adjacent first sub-core layers are in contact to form an integrated structure. At this time, in a cycle, two first spacers are formed between the first spacer of the integrated structure and the second sub-core layer. The second core material layer in the first area is patterned using the first spacers as a mask. Second core layers are formed. Second spacers covering the sidewalls of the second core layers are formed. At this time, in a cycle, five second spacers are formed between the first spacer of the integrated structure and the second sub-core layer. The second spacers are used as a mask to pattern the target material layer via the SAQP process. The SAQP process may be used to form the first target structures with a smaller pitch. Moreover, the first spacer of the integrated structure and the second sub-core layer correspondingly form first sub-target structures with a larger width in the target material layer. The four intervals between five second spacers correspondingly form four second sub-target structures with a smaller width in the target material layer. Forming a unit consisting of two first sub-target structures with a larger width and four second sub-target structures with a smaller width is helpful to adjust the number of the first target structures formed by the SAQP process and obtain units that meet process requirements. For the second area, a first protective layer on the second core material layer is formed in the second area. In the first protective layer, separate first protective layer openings are formed that extend along the first direction and are arranged in parallel along the second direction. The second core material layer is patterned using the first protective layer as a mask. The second core layers are formed and the second spacers covering the sidewalls of the second core layers are made. Then, certain portions of the second core layers in the second area are removed and certain other portions of the second core layers in the second area are retained. The second sidewalls and the remaining second core layers are used as a mask to pattern the target material layer. Second target structures with a larger pitch may be formed using the SALELE process. Thus, embodiments of the present disclosure may better integrate the SAQP process and the SALELE process. Both the first target structures with a smaller pitch and the second target structures with a larger pitch may be formed over the same base. It is conducive to meeting more semiconductor process needs and improving the design freedom in patterning processes through process integration.

In order to make the above objects, features, and advantages of the present disclosure more obvious and understandable, specific embodiments of the present disclosure will be described in detail below in conjunction with the accompanying drawings.

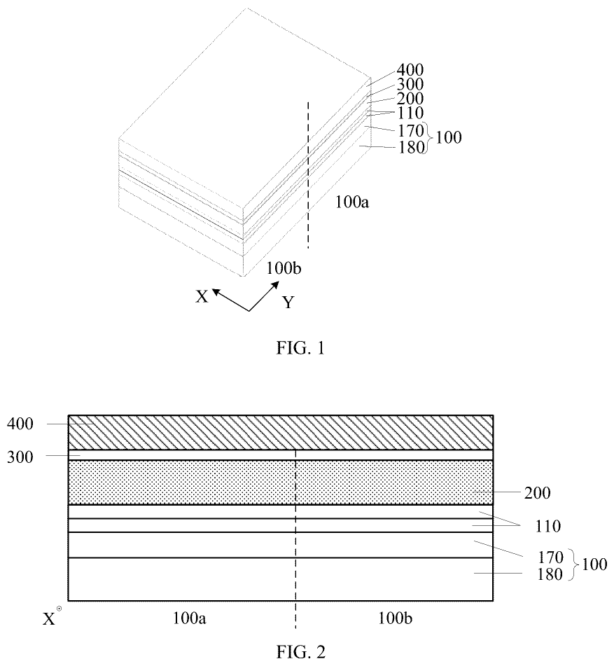

FIGS. 1 to 23 are schematic structural diagrams corresponding to steps of methods for forming a semiconductor structure according to various embodiments of the present disclosure. FIG. 1 is a perspective view, and FIGS. 2 to 22 are cross-sectional views based on FIG. 1.

Referring to FIGS. 1 and 2, a base 100 is provided. The base 100 includes a substrate 180 and a target material layer 170 on the substrate 180. A second core material layer 200 is formed over the base 100, and a first core material layer 400 is formed over the second core material layer 200. The base 100 includes a first area 100a for forming first target structures and a second area 100b for forming second target structures. Both the first target structure and second target structure extend along a first direction (i.e., the X direction in FIGS. 1 and 2). The pitch of adjacent first target structures is smaller than or equal to the pitch of adjacent second target structures.

The base 100 provides a process operation basis for formation processes of semiconductor structures. Exemplarily, the semiconductor structures include metal interconnection lines, barrier layers, adhesion layers, cap layers, etc.

In some embodiments, the substrate 180 is a wafer on which transistors and part of connection lines are formed.

In some embodiments, the base 100 includes a first area 100a used for forming multiple first target structures and a second area 100b used for forming multiple second target structures. The pitch of adjacent first target structures is smaller than or equal to the pitch of adjacent second target structures.

In some embodiments, during formation processes of a semiconductor structure, it is necessary to form denser first target structures and sparser second target structures. For example, the pitch of adjacent first target structures is smaller than or equal to the pitch of adjacent second target structures. The SAQP process may be used to form denser target structures. However, it is hard to use SAQP to create sparser target structures. In addition, the pitch between target structures is relatively fixed and difficult to adjust freely according to layout needs. When the SALELE process is used, the pitch between target structures may be defined according to the layout. Further, the pitch is easy to adjust, and a self-aligned block process may be realized. However, it is difficult to use SALELE to form denser (e.g., a pitch smaller than 38 nm) target structures. In some embodiments, the SAQP process is used in the first area 100a, and the SALELE process is used in the second area 100b. As such, the base 100 including the first area 100a for forming the first target structures and the second area 100b for forming the second target structures indicates the following may be achieved in some embodiments: Fabricating the first target structures with smaller pitches that are difficult to make with SALELE and fabricating the second target structures with larger pitches that are difficult to make with SAQP and having more freedom in design over the same base 100 (e.g., a same wafer).

In some embodiments, the first area 100a is used to form first target structures arranged regularly. The first target structure includes a first sub-target structure with a larger width and a second sub-target structure with a smaller width between two adjacent first sub-target structures. Multiple second sub-target structures are used to form a standard unit. Two adjacent first sub-target structures are used to form a power supply structure of the standard unit.

In some embodiments, the first area 100a includes a logic device area. The second area 100b includes a peripheral device area. The logic device area has denser patterns, and the peripheral device area has sparser patterns. Optionally, the logical device area includes device areas containing a central processing unit (CPU) and a graphics processing unit (GPU), and the peripheral device area includes device areas containing static random-access memory (SRAM), input and output (IO) devices, etc.

Optionally, the pitch of adjacent first target structures is 24 nm to 38 nm and the pitch of adjacent second target structures is 38 nm to 200 nm.

Thus, the SAQP process may be used to form the first target structures, and the SALELE process may be used to form the second target structures. The first target structures with a pitch of 24 nm to 38 nm and the second target structures with a pitch of 38 nm to 200 nm may be formed over the same base 100.

In some embodiments, the thickness of gate oxide layers in the logic device area is smaller than the thickness of gate oxide layers in the peripheral device area. Generally, the operating voltage of CPU or GPU transistors is lower than that of transistors in the IO device area. For example, the operating voltage of CPU transistors may be 0.75 V, while the operating voltage of transistors in an IO device area may be 1.2 V or even 1.8 V. Usually, in order to maintain the reliability and electrical performance of transistors in an IO device area, the gate oxide layer of transistors in the IO device area may be thicker than that in a logic device area.

The thickness difference mainly comes from the thickness of a high-K (HK) dielectric layer of a high-K metal gate (HKMG) and the thickness of an interface layer (e.g., a silicon oxide layer) between transistor channels. In other words, the interface layer in a gate oxide layer of the logic device area is thinner than that in the IO device area, and the HK dielectric layers over the interface layer in the two areas have the same thickness. The interface layer and HK dielectric layer together form a gate dielectric layer of a corresponding transistor. Thus, the thickness of a gate oxide layer in the logic device area is smaller than that in the peripheral device area.

The target material layer 170 is used to provide a process platform for forming the first target structures and the second target structures.

In some embodiments, in the step of providing the base 100, the target material layer 170 is a dielectric layer, the first target structures are first trenches, and the second target structures are second trenches.

The first trench and second trench provide spatial locations for subsequent processes. The target material layer 170 is a dielectric layer used to isolate structures formed in the first trench and second trench.

In some embodiments, materials of the dielectric layer include one or more of silicon oxide, silicon nitride, silicon oxynitride, silicon oxycarbide, silicon carbonitride, silicon oxynitride, a low-K (LK) material (e.g., a material of an LK dielectric layer), and an ultralow-K (ULK) material (e.g., a material of an ULK dielectric layer).

In some embodiments, in the step of providing the base 100, a mask material layer 110 is also formed between the target material layer 170 and the second core material layer 200.

The mask material layer 110 is used to subsequently form a second pattern transfer layer.

In some embodiments, the mask material layer 110 has a stacked structure, including a titanium nitride layer and a silicon oxide layer over the titanium nitride layer.

The second core material layer 200 is used to subsequently form second core layers and third core layers.

In some embodiments, after the second core layers are subsequently formed, the second core layers will be removed later. Thus, the material of the second core material layer 200 may be a material that is easy to remove, thereby reducing the difficulty of removing the second core layers and reducing the damage to other layers located below the second core material layer 200. Materials of the second core material layer 200 may include one or more of amorphous silicon, polycrystalline silicon, single crystal silicon, silicon oxide, advanced patterning film (APF) material, spin on carbon (SOC), and silicon carbide. For example, the material of the second core material layer 200 may be amorphous silicon (a-Si) in some cases.

In some embodiments, in the step of providing the base 100, an etching stop layer 300 may be also formed between the first core material layer 400 and the second core material layer 200.

The etching stop layer 300 is used to subsequently form a first pattern transfer layer. The etching stop layer 300 is also used as an etch stop layer when the first core material layer 400 is subsequently patterned, and to protect the second core material layer 200 and prevent the second core material layer 200 from being damaged.

In some embodiments, materials of the etching stop layer 300 include one or more of silicon oxide, silicon nitride, silicon oxynitride, silicon carbide, titanium, titanium oxide, titanium nitride, tantalum, tantalum oxide, tantalum nitride, boron nitride, copper nitride, aluminum nitride, and tungsten nitride. For example, the material of the etching stop layer 300 may be silicon oxide in some cases.

The first core material layer 400 is used to subsequently form the first core layers.

In some embodiments, after the first core layers are subsequently formed, the first core layers will be removed later. Thus, the material of the first core material layer 400 may be a material that is easy to remove, thereby reducing difficulties of removing the first core layers and reducing damage to other layers located below the first core material layer 400. Materials of the first core material layer 400 may include one or more of a-Si, polycrystalline silicon, single crystal silicon, silicon oxide, APF material, SOC, and silicon carbide. For example, the material of the first core material layer 400 may be a-Si in some cases.

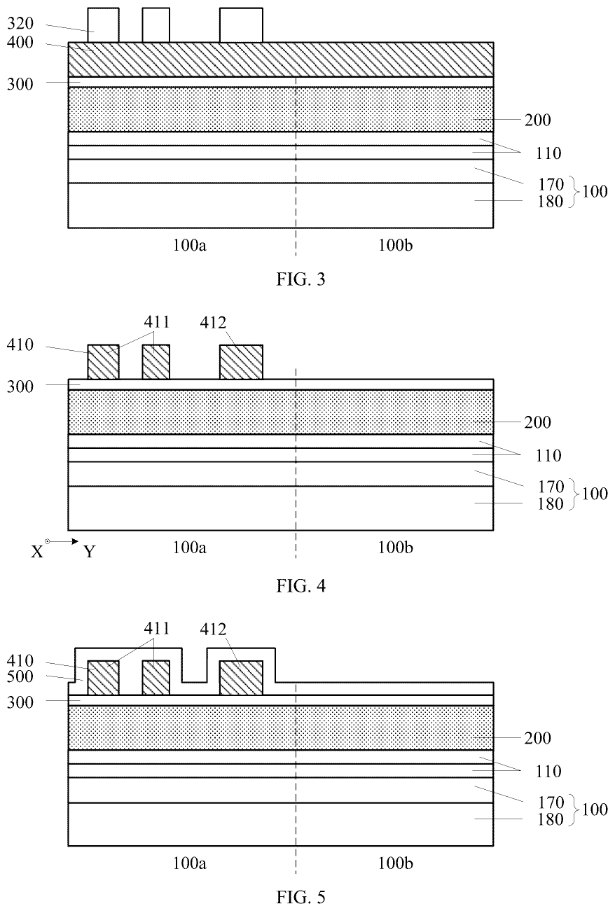

With reference to FIGS. 3 and 4, the first core material layer 400 is patterned, and first core layers 410 are formed separately in the first area 100a. The first core layers 410 extend along the first direction (i.e., the X direction in FIG. 4) and are arranged in parallel along the second direction (i.e., the Y direction in FIG. 4). Along the second direction, first core layers 410 are arranged, with two adjacent first sub-core layers 411 and one second sub-core layer 412 being distributed alternately. The width of the second sub-core layer 412 is greater than the width of the first sub-core layer 411. As aforementioned, the first direction is perpendicular to the second direction.

The first core layers 410 are used to provide support for the subsequent formation of the first spacers. Two adjacent first sub-core layers 411 and one second sub-core layer 412 form a cycle. The first core layers 410 are composed of multiple cycles along the second direction. As the width of the second sub-core layer 412 is greater than the width of the first sub-core layer 411, the width of the first target structure correspondingly formed by the second sub-core layer 412 in the target material layer 170 is larger than the width of a corresponding first target structure formed by the first sub-core layer 411 in the target material layer 170.

In some embodiments, the first core material layer 400 is patterned using a dry etching process. The dry etching of a-Si is easier to stop at the silicon oxide material used as the first etching stop layer 300 in the embodiments.

The dry etch process is an etching process with anisotropic etching characteristics, and its longitudinal etching rate is much greater than the lateral etching rate. Therefore, by selecting a dry etching process, it is beneficial to improve the accuracy of pattern transfer. At the same time, dry etching is more directional and conducive to improving the sidewall topography quality and dimensional accuracy of the first core layers 410.

Correspondingly, in some embodiments, the material of the first core layers 410 is a-Si, so that during the process of patterning the first core material layer 400, damage to the etching stop layer 300 is reduced. After the first core material layer 400 is patterned, the etching stop layer 300 still maintains a good size and topography accuracy. Moreover, the first core layers 410 are made of a material that is easy to remove, and the subsequent removal process of the first core layers 410 has less impact on the etching stop layer 300.

Notably in some embodiments, the size and pitch of the first core layers 410 are set according to the size and pitch of the first target structures subsequently formed in the first area 100a.

Referring to FIG. 3, the step of patterning the first core material layer 400 includes forming first mask layers 320 separately over the first core material layer 400 in the first area 100a.

The first mask layers 320 are used as an etching mask for patterning the first core material layer 400.

In some embodiments, the first mask layer 320 includes an SOC layer, an anti-reflective coating (Si-ARC) on the SOC, and a photoresist layer on the Si-ARC. The first mask layer 320 may be formed through photolithography and several etching steps.

Referring to FIG. 4, the first core material layer 400 is patterned via the first mask layers 320. First core layers 410 are formed separately in the first area 100a.

In some embodiments, after the first core layers 410 are formed, the process also includes removing the first mask layers 320.

The first mask layers 320 are removed to prepare for subsequent formation of the first spacers.

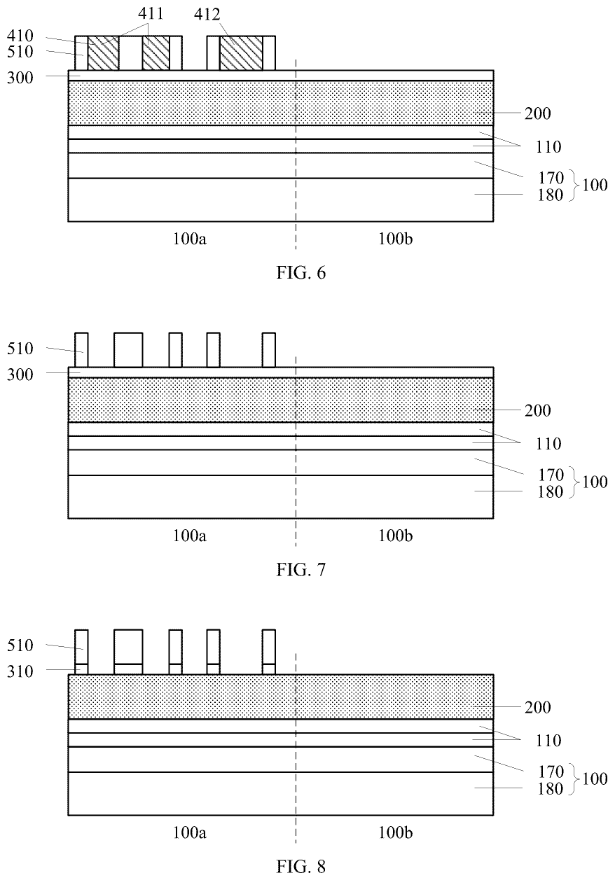

Referring to FIGS. 5 and 6, first spacers 510 are formed that cover the sidewalls of the first core layers 410. First spacers 510 of opposite sidewalls of adjacent first sub-core layers 411 contact each other to form integrated structures.

The first spacers 510 are used as a mask for subsequently patterning the second core material layer 200. After the first spacers 510 of opposite sidewalls of adjacent first sub-core layers 411 contact each other to form the integrated structures, the integrated structures are used to form first spacers 510 with a larger width. The first spacers 510 with the larger width are subsequently used to form second core layers with a larger width in the second core material layer 200. Second spacers covering the sidewalls of the second core layers are then formed, with a larger spacing between second spacers. Then the larger spacing is passed to the target material layer 170, and then first sub-target structures with a larger width are formed.

In some embodiments, materials of the first spacers 510 include one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may form a better etching selectivity ratio with respect to the first core layers 410, thereby reducing the damage to the first spacers 510 in subsequent steps of removing the first core layers 410.

Referring to FIG. 5, the step of forming the first spacers 510 covering the sidewalls of the first core layers 410 includes forming a first spacer material layer 500 covering the sidewalls and top of the first core layers 410 and the top of the second core material layer 200. Portions of the first spacer material layer 500 on opposite sidewalls of adjacent first sub-core layer 411 contact each other.

In some embodiments, the first spacer material layer 500 covers the sidewalls and top of the first core layers 410 and the top of the etching stop layer 300.

The first spacer material layer 500 is used to form the first spacers 510 directly. Correspondingly, materials of the first spacer material layer 500 include one or more of titanium oxide, titanium nitride, silicon oxide, silicon nitride, silicon oxynitride, and silicon carbide.

In some embodiments, the ALD process is used to form the first spacer material layer 500 that covers the sidewalls and top of the first core layers 410 and the top of the etching stop layer 300.

The first spacer material layer 500 formed by the ALD process has good thickness uniformity and good step coverage capability. As such, the first spacer material layer 500 may conformally cover the sidewalls and top of the first core layers 410 and the top of the second core material layer 200.

Referring to FIG. 6, portions of the first spacer material layer 500 located on top of the first core layers 410 and the second core material layer 200 are removed. Portions of the first spacer material layer 500 located on the sidewalls of the first core layers 410 are retained as the first spacers 510.

In some embodiments, portions of first spacer material layer 500 on top of the first core layers 410 and on top of the etch stop layer 300 are removed.

Optionally, portions of the first spacer material layer 500 on top of the first core layers 410 and on top of the etch stop layer 300 may be removed by dry etch.

Dry etch is an anisotropic etching process. As such, the dry etching process is beneficial to reduce the damage to the first core layers 410 and the etching stop layer 300.

Further, dry etch is more directional on etching, which is beneficial to improve the sidewall topography quality and dimensional accuracy of the first spacers 510.

Referring to FIG. 7, the first core layers 410 are removed.

Removing the first core layer 410 is used to prepare for subsequent patterning of the etching stop layer 300 and the second core material layer 200 using the first spacers 510 as a mask.

In some embodiments, a wet etching process is used to remove the first core layers 410.

Wet etch has characteristics of isotropic etching, which is conducive to removing the first core layers 410 completely. Moreover, the cost of wet etch is relatively low, the operation steps are simple, and it may also achieve a large etch selectivity ratio. It is beneficial to reduce the damage to the first spacers 510 during the process of removing the first core layers 410.

Referring to FIG. 8, before patterning the second core material layer 200 using the second protective layer as a mask, the first spacers 510 are used as a mask to pattern the etching stop layer 300 and first pattern transfer layers 310 are made.

The first pattern transfer layers 310 are used as an etching mask for subsequent patterning of the second core material layer 200 in the first area 100a.

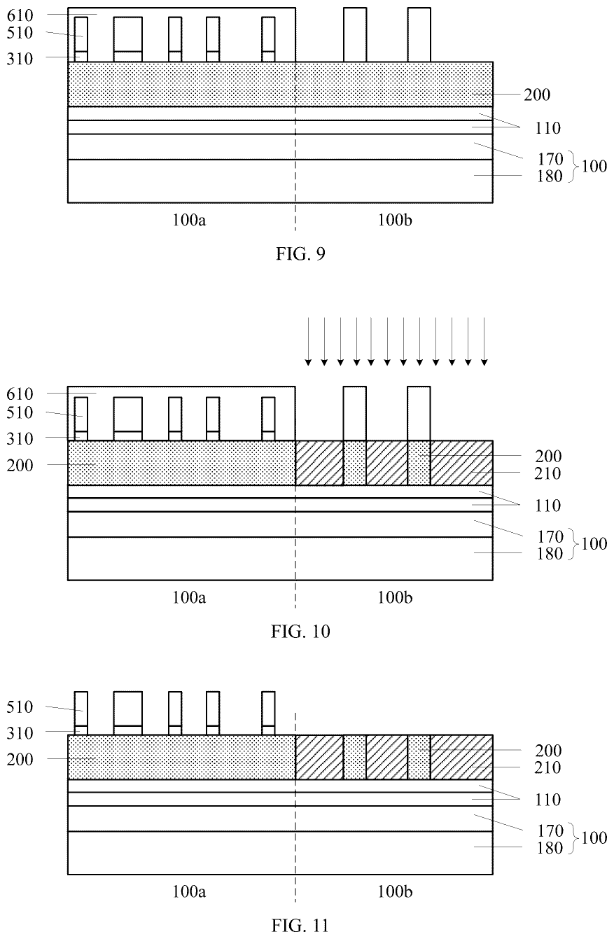

With reference to FIG. 9, before the subsequent formation of the first protective layer on the second core material layer 200 in the second area 100b, the formation method further includes forming multiple second protective layers 610 separately on the second core material layer 200 in the second area 100b and a second protective layers 610 that covers the second core material layer 200 and the first spacers 510 in the first area 100a.

The second protective layer 610 in the first area 100a is used to cover the first area 100a and protect the first spacers 510 and the second core material layer 200 in the first area 100a from damage. The second protective layers 610 in the second area 100b are used as an implantation mask for subsequent ion implantation in the second core material layer 200 in the second area 100b.

In some embodiments, materials of the second protective layer 610 include SOC.

In some embodiments, the step of forming the second protective layers 610 that are separately arranged over the second core material layer 200 in the second area 100b and cover the second core material layer 200 and the first spacers 510 in the first area 100a includes forming a second protective material layer covering the second core material layer 200 and the first spacers 510.

The second protective material layer is used to form the second protective layers 610.

In some embodiments, the second protective material layer is a planarization layer, and materials of the second protective material layer include SOC. SOC may be formed by a spin-coating process with low cost. By using SOC, it is beneficial to improve the flatness of the top surface of the second protective material layer, thereby providing a good interface for the formation of the first protective layers.

In some embodiments, the second protective material layer also covers sidewalls of the first pattern transfer layers 310 in the first area 100a.

In some embodiments, second mask layers are formed on the second protective material layer. The second mask layers cover the second protective material layer in the first area 100a and are separately arranged over the second protective material layer in the second area 100b.

The second mask layers are used to pattern the second protective material layer.

In some embodiments, the second mask layer includes Si-ARC and a photoresist layer located over the Si-ARC.

In some embodiments, the second protective material layer in the second area 100b is patterned. Portions of the second protective material layers are separately formed in the second area 100b, and retained to cover the second core material layer 200 in the first area 100a. The second protective material layers in the first and second areas collectively become or are collectively used as the second protective layers 610.

In some embodiments, the second protective material layer is patterned using the second mask layer as an etching mask.

Optionally, after patterning the second protective material layer in the second area 100b, the formation method also includes removing the second mask layer.

Referring to FIG. 10, certain portions of the second core material layer 200 in the second area 100b are modified by changing the etching property using the second protective layers 610 as a mask, which forms third core material layers 210 having an etching selectivity ratio with respect to the remaining second core material layers 200. The remaining second core material layers 200 are separately arranged in the second area 100b and surrounded by the third core material layers 210 in the second area 100b.

Portions of the second core material layer 200 in the second area 100b are modified by changing the etching property and the third core material layers 210 are fabricated that have an etching selectivity ratio with respect to the remaining second core material layers 200. As such, it makes it easy to remove the remaining second core material layers 200 later. Further, in the process of removing the remaining second core material layers 200, damage to the third core material layers 210 is reduced. The third core material layers 210 are used to prepare for subsequent patterning of the target material layer 170 in the second area 100b.

In some embodiments, in the step of modifying the etch property of the portions of the second core material layer 200 in the second area 100b using the second protective layers 610 as a mask, an ion implantation process is performed in the portions of the second core material layer 200 in the second area 100b, and the third core material layers 210 are formed that have an etching selectivity ratio with respect to the remaining second core material layers 200.

The ion implantation process has characteristics of uniform injection of ions into a large area with more accurate control of ion doping depth and high repeatability. Using ion implantation to obtain the third core material layers 210 is beneficial to accurately control the doping concentration and distribution in the third core material layers 210 and the penetration depth in the second core material layer 200. It makes the ion distribution in the third core material layer 210 relatively uniform.

In some embodiments, in the step of performing ion implantation in the second core material layer 200 using the second protective layers 610 as a mask, the ions implanted in the ion implantation process include one or more of boron, phosphorus, arsenic, boron chloride, boron dichloride, and carbon.

In some embodiments, the material of the second core material layer 200 is a-Si. After implanting one or more ions of boron, phosphorus, arsenic, boron chloride, boron dichloride, and carbon into the second core material layer 200, a-Si may be converted into a material having a higher etching selectivity ratio with respect to a-Si, thereby obtaining the third core material layers 210 having a higher etching selectivity with respect to the second core material layer 200.

Notably in some embodiments, a photomask and a photolithography etching process are used to pattern the second mask layer in the second area 100b and the second mask layer in the first area 100a. The second protective material layer is patterned using the second mask layer to form the second protective layers 610. Then, the second core material layer 200 is processed using ion implantation with the second protective layers 610 as a mask. The third core material layers 210 are formed that have an etching selectivity ratio with respect to the second core material layers 200. The process flexibility of forming the second protective layers 610 is relatively high. The width and pitch of the second protective layers 610 are easy to adjust, which accordingly makes the width and pitch of the remaining second core material layers 200 in the second area 100b easy to adjust. Thus, second target structures with a larger pitch may be obtained in the second area 100b, and the degree of freedom of pattern design may be improved.

In some embodiments, in the step of modifying the etch property of the portions of the second core material layer 200 in the second area 100b using the second protective layers 610 as a mask, the size of the remaining second core material layers 200 along the second direction is 35 nm to 200 nm, and the pitch is 76 nm to 200 nm. The size of the third core material layers 210 along the second direction is 35 nm to 200 nm, and the pitch is 76 nm to 200 nm.

In some embodiments, the second mask layer 330 in the first area 100a is not removed when the second mask layer 330 is patterned using a photomask and photolithography etching process. Therefore, the second protective layers 610 in the first area 100a still completely cover the first spacers 510 in the first area 100a and the second core material layer 200 in the first area 100a. None of the second core material layers 200 in the first area 100a is modified to change etch property and become a part of the third core material layer 210.

Referring to FIG. 11, after the third core material layers 210 are made, the formation method also includes removing the second protective layers 610.

The second protective layers 610 are removed to prepare for the subsequent formation of the first protective layer.

In some embodiments, an etching process is implemented to remove the second protective layers 610.

In some embodiments, either isotropic or anisotropic etching process may be used. It only needs to ensure the etching selectivity ratio of the etching process. The etching process has a relatively large etching selectivity ratio between the second protective layers 610 and the first spacers 510, thereby reducing damage to the first spacers 510 during the removal of the second protective layers 610.

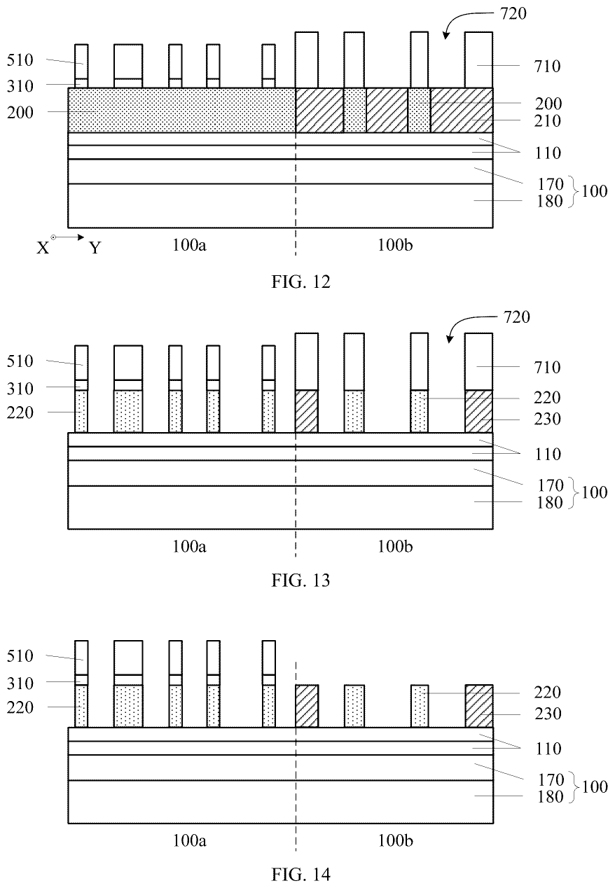

Referring to FIG. 12, first protective layers 710 are formed over the second core material layers 200 in the second area 100b. The first protective layers 710 are formed with first protective layer openings 720 extending along the first direction and arranged in parallel along the second direction. As aforementioned, the first direction is perpendicular to the second direction.

The first protective layers 710 are used as an etching mask for subsequent patterning of the second core material layers 200.

In some embodiments, the first protective layers 710 are patterned from a planarization layer. Materials of the first protective layers 710 include SOC or SOC and remaining parts of third mask layers 340. Whether some of the third mask layers 340 remains is related to the process selection and does not affect subsequent steps. SOC is formed by a spin-coating process. The cost of spin-coating process is low. Moreover, by using spin-coated carbon, it is helpful to improve the flatness of the top surface of the planarization layer, thereby providing a good interface for the formation of the first protective layers 710.

In some embodiments, in the step of forming the first protective layers 710 on the second core material layers 200 in the second area 100b, the first protective layers 710 are separately formed over the second core material layer 200 and the third core material layers 210.

Correspondingly, the first protective layers 710 are also used as an etching mask for subsequent patterning of the third core material layers 210.

In some embodiments, the step of forming the first protective layers 710 over the second core material layers 200 and the third core material layers 210 in the second area 100b includes forming a first protective material layer covering the second core material layers 200, the third core material layers 210, the first spacers 510, and sidewalls of the first pattern transfer layers 310.

In some embodiments, a third mask layer is also formed on the first protective material layer. The third mask layer exposes the first protective material layer in the first area 100a and is over the first protective material layer in the second area 100b.

The third mask layer is used to pattern the first protective material layer.

In some embodiments, the third mask layer includes Si-ARC and a photoresist layer on the Si-ARC.

In some embodiments, a photomask, certain related photolithography, and etching processes are used to pattern the third mask layer in the first area 100a and second area 100b. The first protective material layer is patterned using the third mask layer. The first protective layers 710 are formed. Then, the second core material layers 200 and the third core material layers 210 are patterned using the first protective layers 710 in the second area 100b and the first spacers 510 in the first area as a mask. Third core layers having an etching selectivity ratio with respect to the second core layers in the second area and second core layers under the first spacers 510 in the first region are formed. Due to the high process flexibility and diverse patterns of using one photomask to define the formation of the third mask layer, the design is relatively free within a range allowed by a single photolithography. As such, the size and pitch of the first protective layer openings 720 in the first protective layer 710 are relatively easy to adjust, as long as they meet the single DUV photolithography limit and the pitch is greater than about 76 nm.

In some embodiments, the first protective material layer is patterned. The first protective material layer in the first area 100a is removed and the first spacers 510 in the first area 100a are exposed. In the second area 100b, parts of the first protective material layer with length extension along the first direction and width extension along the second direction are removed, while the remaining parts of first protective material layer in the second area 100b are retained as the first protective layers 710.

Optionally, the first protective material layer is patterned using the third mask layer as an etching mask.

In some embodiments, after forming separately the first protective layers 710 over the second core material layers 200 and the third core material layers 210 in the second area 100b, the formation method also includes removing the third mask layer.

Referring to FIG. 13, the second core material layers 200 are patterned using the first protective layers 710 and the first spacers 510 as a mask and second core layers 220 are formed.

The second core layers 220 are used to provide support for subsequently forming the second spacers.

Correspondingly in some embodiments, in the step of patterning the second core material layers 200 using the first protective layers 710 and the first spacers 510 as a mask and forming the second core layers 220, the third core material layers 210 are also patterned using the first protective layers 710 as a mask and third core layers 230 corresponding to the third core material layers 210 are formed.

The second core material layers 200 and the third core material layers 210 in the second region 100b are patterned along the first protective layer openings 720 of the first protective layers 710. The second core layers 220 corresponding to the second core material layers 200 and the third core layers 230 corresponding to the third core material layers 210 are formed.

The second core layers 220 are formed by patterning the second core material layer 200 in the second area 100b, and the third core layers 230 are formed by patterning the third core material layer 210 in the second area 100b. The original second core material layer 200 and the third core material layer 210 do not disappear in the patterning processes due to the etching selectivity ratio generated by the etch property modification. The second core layers 220 and the third core layers 210 still retain a high etching selectivity ratio between them. For example, during an etching process with the KOH or SC1 solution, the second core layers 220 may be removed at a faster etching rate, while there is almost no loss to the third core layers 230.

After the second core layers 220 are subsequently removed, the third core layers 230 serve as a partial etching mask for subsequently patterning the target material layer 170 in the second area 100b. The third core layers 230 are also used to provide support for the subsequent formation of the second spacers.

In some embodiments, materials of the second core layer 220 include a-Si, and materials of the third core layer 230 include a-Si doped with boron, phosphorus, or arsenic.

In some embodiments, in the step of patterning the second core material layer 200 in the first area 100a using the first spacers 510 as a mask, the second core material layer 200 in the first area 100a is patterned using the first pattern transfer layer 310 as a mask and the second core layers 220 are separately formed in the first area 100a.

As the second core material layer 200 in the first area 100a is patterned using the first pattern transfer layer 310 as a mask and the second core layers 220 are formed separately in the first area 100a, it is beneficial to improve the accuracy of pattern transfer, thereby helping improve the accuracy of pattern size of the second core layers 220.

Notably, the second core layers 220 in the first area 100a are transferred from the first spacers 510, and the pitch of the first spacers 510 has been reduced by half based on the pitch of the first mask layer. This is also an SADP process, which reduces the etching limit of a single DUV photolithography from about 80 nm to about 40 nm. This prepares for the subsequent formation of the second spacers on the sidewalls of the second core layers 220, which achieves another halving of the pitch, when the pitches of the second spacer and the first spacer 510 are compared. This is also the characteristic of the SAQP process and the reason why SAQP may form patterns with a pitch of about 24 nm.

In some embodiments, in the same step, the second core material layers 200 in the first area 100a are patterned using the first spacers 510 and the first pattern transfer layer 310 as a mask. The second core material layers 200 and the third core material layers 230 in the second area 100b are patterned using the first protective layer openings 720 of the first protective layers 710.

In the same step, the second core material layers 200 in the first area 100a are patterned using the first spacers 510 as a mask and the second core material layers 200 and the third core material layers 230 in the second area 100b are patterned using the first protective layers 710 as a mask. It helps simplify the process flow and improve process efficiency.

Referring to FIG. 14, the first protective layers 710 are removed.

Removing the first protective layers 710 is used to prepare for subsequent removal of the second core layers 220.

Optionally, a dry etching process is used to remove the first protective layers 710.

In some embodiments, either isotropic or anisotropic etching process may be used. It is only necessary to ensure the etching selectivity ratio of an etching process, so that the etching process has a relatively large etching selectivity between the first protective layers 710 and the first spacers 510. As such, during the process of removing the first protective layers 710, the damage to the first spacers 510 is reduced.

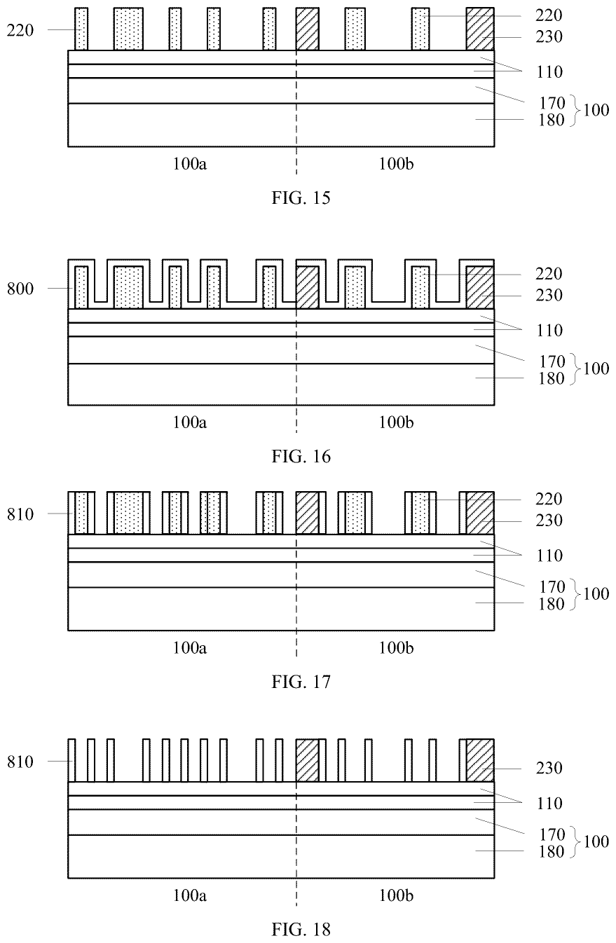

Referring to FIG. 15, the first spacers 510 are removed.

Removing the first spacers 510 is used to prepare for the subsequent formation of the second spacers.

In some embodiments, after forming the second core layers 220, the formation method also includes removing the first pattern transfer layers 310.

The first pattern transfer layers 310 are removed to prepare for the subsequent formation of the second spacers.

In some embodiments, a wet etching process is used to remove the first spacers 510 and the first pattern transfer layers 310.

The wet etching process has isotropic etching characteristics, which is beneficial to remove the first spacers 510 and the first pattern transfer layers 310 cleanly. Moreover, the cost of a wet etching process is relatively low, the operation steps are simple, and it may also achieve a large etching selectivity ratio. It is beneficial to reduce the damage to the second core layers 220 during the process of removing the first spacers 510 and the first pattern transfer layers 310.

With reference to FIGS. 16 and 17, second spacers 810 covering sidewalls of the second core layers 220 are formed.

The second spacers 810 are used as a partial etching mask for subsequent patterning of the target material layer 170 in the first area 100a and the second area 100b.

Correspondingly, in some embodiments, in the step of forming the second spacers 810 covering the sidewalls of the second core layers 220, the second spacers 810 covering the sidewalls of the second core layers 220 and the third core layers 230 are formed.

In some embodiments, materials of the second spacers 810 include one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may form a better etching selectivity ratio with respect to the second core layers 220 and the third core layers 230. As such, damages to the second spacers 810 may be reduced in a subsequent step of removing the second core layers 220.

Referring to FIG. 16, the step of forming the second spacers 810 covering the sidewalls of the second core layers 220 includes forming a second spacer material layer 800 covering the sidewalls and top of the second core layers 220 and the top of the base 100.

The second spacer material layer 800 is used to directly form the second spacers 810. Correspondingly, materials of the second spacer material layer 800 include one or more of titanium oxide, titanium nitride, silicon oxide, silicon nitride, silicon oxynitride, and silicon carbide.

Correspondingly, in some embodiments, a second spacer material layer 800 is formed that covers the sidewalls and top of the second core layers 220 and the third core layers 230 and the top of the base 100.

In some embodiments, ALD is used to form the second spacer material layer 800 covering the sidewalls and top of the second core layers 220 and the third core layers 230 and the top of the base 100.

The second spacer material layer 800 formed by ALD has good thickness uniformity and good step coverage capability. It enables the second spacer material layer 800 to conformally cover the sidewalls and top of the second core layers 220 and the third core layers 230 and the top of the base 100.

Referring to FIG. 17, the second spacer material layer 800 on the top of the second core layers 220 and the base 100 is removed, and the second spacer material layer 800 on the sidewalls of the second core layers 220 are retained as the second spacers 810.

Correspondingly, in some embodiments, the second spacer material layer 800 on the top of the third core layers 230 is also removed, and the second spacer material layers 800 on the sidewalls of the third core layers 230 are retained as the second spacers 810.

In some embodiments, a dry etching process is used to remove the second spacer material layer 800 on top of the second core layers 220 and the third core layers 230 and on the top of the base 100.

The dry etching process is an anisotropic dry etch process. Thus, by selecting the dry etching process, it is beneficial to reduce the damage to the second core layers 220 and the third core layers 230. At the same time, dry etching is more directional, which is beneficial to improve the sidewall topography quality and dimensional accuracy of the second spacers 810.

In some embodiments, the second spacer material layer 800 on the top of the second core layers 220 and the third core layers 230 and the top of the base 100 is removed to expose the top of the second core layers 220 and the third core layers 230.

Referring to FIG. 18, the second core layers 220 in the first area 100a and part of the second core layers 220 in the second area 100b are removed.

Specifically, in some embodiments, second core layers 220 in the first area 100a and the second area 100b are removed, and the third core layers 230 are retained.

The second core layers 220 are removed to prepare for subsequent patterning of the target material layer 170 in the first area 100a and the second area 100b using the second spacers 810 and the third core layers 230 as a mask.

In some embodiments, a wet etching process is used to remove the second core layers 220 in the first area 100a and part of the second core layers 220 in the second area 100b.

The wet etching process has characteristics of isotropic etching, which is beneficial to remove the second core layers 220 cleanly. Further, the cost of a wet etching process is relatively low, the operation steps are simple, and it may also achieve a large etching selectivity ratio, which is beneficial to reduce the damage on the second spacers 810 during the process of removing the second core layers 220.

In some embodiments, in the step of removing the second core layers 220 using the wet etching process, the etching solution of the wet etch includes one or more of KOH solution, THMA solution, and SC1 solution.

In some embodiments, the second core layers 220 contain an undoped silicon material, and the third core layers 230 contain a doped silicon material. KOH solution or THMA solution may have a high etching rate for undoped silicon but almost no etch on doped silicon (especially silicon doped with B ions). Therefore, using KOH solution or THMA solution as an etching solution may remove the second core layers 220 cleanly while reducing the damage to the third core layers 230.

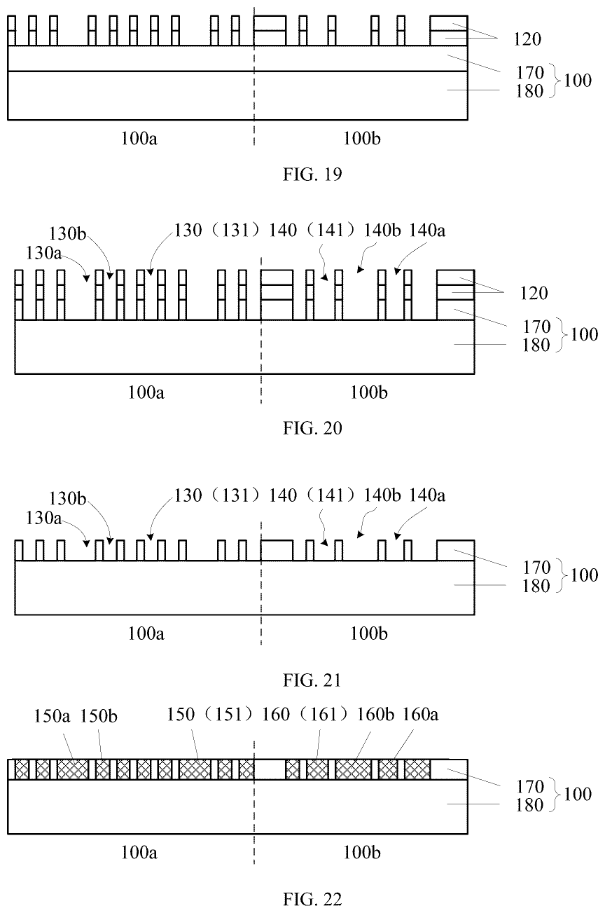

With reference to FIGS. 19 and 20, the target material layer 170 is patterned using the second spacers 810 and the remaining second core layers 220 as a mask. First target structures 131 in the first area 100a and second target structures 141 in the second area 100b are formed. First target structures 131 corresponding to intervals between adjacent first sub-core layers 411 and corresponding to the second sub-core layers 412 are the first sub-target structures 130a. First target structures 131 between adjacent first sub-target structures 130a are the second sub-target structures 130b. Both the first target structures 131 and the second target structure 141 extend along the first direction. The pitch of adjacent first target structures 131 is smaller than or equal to the pitch of adjacent second target structures 141.

In some embodiments, for the first area 100a, the first core layers 410 show two adjacent first sub-core layers 411 and one second sub-core layer 412 formed in an alternating arrangement. The width of the second sub-core layer 412 is greater than the width of the first sub-core layer 411. Two adjacent first sub-core layers 411 and one second sub-core layer 412 are used as a cycle, and first spacers 510 of opposite sidewalls of adjacent first sub-core layers 411 are in contact to form an integrated structure. At this time, in a cycle, two first spacers 510 are formed between the first spacer 510 of the integrated structure and the second sub-core layer 412. The second core material layers 200 in the first area 100a are patterned using the first spacers 510 as a mask. The second core layers 220 are formed, and the second spacers 810 covering sidewalls of the second core layers 220 are formed. At this time, in a cycle, five second spacers 810 are formed between the first spacer 510 of the integrated structure and the second sub-core layer 412. The target material layer 170 is patterned using the second spacers 810 as a mask. The SAQP process is performed. The SAQP process may form first target structures 131 with a smaller pitch. Moreover, the first spacer 510 and the second sub-core layer 412 of the integrated structure form a first sub-target structure 130a with a larger width in the target material layer 170. The four intervals among five second spacers 810 correspondingly form four second sub-target structures 130b with a smaller width in the target material layer 170. A unit is formed that consists of two first sub-target structures 130a with a larger width and four second sub-target structures 130b with a smaller width. It is beneficial to adjust the number of first target structures 131 formed in the SAQP process and obtain units that meet process requirements. For the second area 100b, a first protective layer 710 is formed over the second core material layer 200 in the second area 100b. Separate first protective layer openings 720 extending along the first direction and arranged in parallel along the second direction are formed in the first protective layer 710. The second core material layers 200 are patterned using the first protective layers 710 as a mask. The second core layers 220 are formed, and the second spacers 810 covering sidewalls of the second core layers 220 are formed. Then certain parts of the second core layers 220 in the second area 100b are removed, and some other parts of the second core layers 220 in the second area 100b are retained. The target material layer 170 is patterned using the second spacers 810 and the remaining second core layers 220 as a mask. The SALELE process may form second target structures 141 with a larger pitch. Thus, embodiments of the present disclosure may better integrate the SAQP process and the SALELE process. Over the same base 100, both the first target structures 131 with a smaller pitch and the second target structures 141 with a larger pitch may be formed. It is conducive to meeting more semiconductor process needs through process integration and improving the design freedom in patterning processes.

In some embodiments, in the step of patterning the target material layer 170 using the second spacers 810 and the remaining second core layers 220 as a mask, the second spacers 810 and the third core layers 230 are used as a mask to pattern the target material layer 170.

In some embodiments, as aforementioned, the distance between adjacent first sub-core layers 411 and the size of the second sub-core layer 412 are used to determine the size of the first sub-target structure 130a. Optionally, in the step of patterning the first core material layer 400 and forming the first core layers 410 separately in the first area 100a, the distance between adjacent first sub-core layers 411 is equal to the preset width of the first sub-target structure 130a, and the width of the second sub-core layer 412 is equal to the sum of the preset width of the first sub-target structure 130a and twice the preset width of the second spacer 810.

As aforementioned, in the cycle of two adjacent first sub-core layers 411 and one second sub-core layer 412, the size of the first sub-core layer 411 and the distance between adjacent first sub-core layer 411 and second sub-core layer 412 are used to determine the size of the second sub-target structure 130b. In some embodiments, in the step of patterning the first core material layer 400 and forming the first core layers 410 separately in the first region 100a, the width of the first sub-core layer 411 is equal to the sum of the preset width of the second sub-target structure 130b and twice the preset width of the second spacer 810. The distance between adjacent first sub-core layer 411 and the second sub-core layer 412 is equal to the sum of the preset width of the second sub-target structure 130b, twice the preset width of the second spacer 810, and twice the preset width of the first spacer 510.

In some embodiments, in the step of patterning the target material layer 170 using the second spacers 810 and the remaining second core layers 220 (or the third core layers 230) as a mask, and forming the first target structures 131 in the first area 100a and the second target structures 141 in the second area 100b, the formation method further includes patterning the dielectric layer using the second spacers 810 and the third core layers 230 as a mask and forming first trenches 130 and second trenches 140 in the dielectric layer.

The first trenches 130 provide a spatial location for the subsequent formation of the first metal lines. The second trenches 140 provide a spatial location for the subsequent formation of the second metal lines.

The second trenches 140 may be divided into A-type second trenches 140a and B-type second trenches 140b. The A-type second trenches 140a are certain second trenches 140 corresponding to the second core layers 220. The B-type second trenches 140b are certain second trenches 140 corresponding to grooves surrounded by the second spacer material layers 800 on sidewalls of the second core layers 220 and the third core layers 230.

Referring to FIG. 19, the step of patterning the target material layer 170 using the second spacers 810 and the remaining second core layers 220 (or the third core layers 230) as a mask includes patterning the mask material layer 110 using the second spacers 810 and the third core layers 230 as a mask and forming second pattern transfer layers 120.

The second pattern transfer layers 120 are used as an etching mask for patterning the target material layer 170.

In some embodiments, after forming the second pattern transfer layers 120 and before patterning the target material layer 170 using the second pattern transfer layers 120 as a mask, the formation method further includes removing the second spacers 810 and the third core layers 230 to prepare for subsequent patterning of the target material layer 170 using the second pattern transfer layers 120 as a mask.

Referring to FIG. 20, the target material layer 170 is patterned using the second pattern transfer layers 120 as a mask.

The patterns of the second spacers 810 and the third core layers 230 are transferred to the target material layer 170 through the second pattern transfer layers 120, which is beneficial to improve the accuracy of pattern transfer. As such, the dimensional accuracy of the first target structures 131 and the second target structures 141 is higher.

Notably, an etching process is used to pattern the target material layer 170 using the second pattern transfer layers 120 as a mask, thereby thinning the second pattern transfer layers 120 in the step of patterning the target material layer 170. For example, the silicon oxide layer in the second pattern transfer layers 120 may be removed.

Referring to FIG. 21, after forming the first target structures 131 and second target structures 141, the formation method also includes removing the second pattern transfer layers 120.

Removing the second pattern transfer layers 120 is arranged to prepare for the subsequent formation of the first metal lines and the second metal lines.

Referring to FIG. 22, after forming the first target structures 131 in the first area 100a and the second target structures 141 in the second area 100b, the formation method further includes forming first metal lines 150 in the first trenches 130 and forming second metal lines 160 in the second trenches 140.

The first metal lines 150 and second metal lines 160 are metal interconnection lines in the back-end process.

Optionally, the first metal lines 150 may be divided into A-type first metal lines 150a with a larger width and B-type first metal lines 150b with a smaller width. Four B-type first metal lines 150b are formed between adjacent A-type first metal lines 150a.

Similarly, the second metal lines may also be divided into A-type second metal lines 160a and B-type second metal lines 160b. The A-type second metal lines 160a are metal lines corresponding to the second core layers 220. The B-type second metal lines 160b are metal lines corresponding to grooves surrounded by the second spacer material layers 800 on sidewalls of the second core layers 220 and the third core layers 230. The A-type second metal lines 160a and the B-type second metal lines 160b may be spaced apart from each other, and the pitch between them, the width, and the length may be adjusted. Thus, they are more flexible in design compared to the first metal lines 150.

A dielectric layer is an inter metal dielectric (IMD) layer. The dielectric layer is used to achieve electrical isolation between metal interconnect lines in the back end of line (BEOL) process.

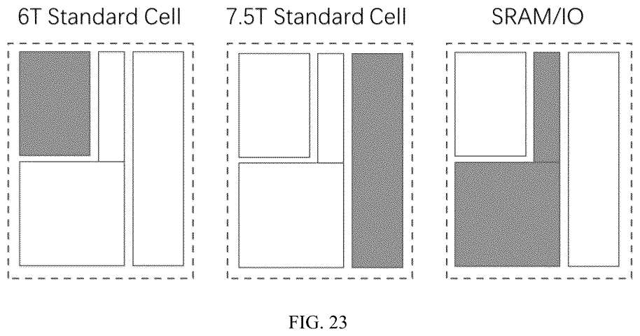

Exemplarily, as shown in FIG. 23, formation methods for some embodiments are illustrated. A 6 T standard cell area, a 7.5T standard cell area, and an SRAM/input-output area (SRAM/IO) are formed on the base. The black areas mark corresponding device areas.

Specifically, in the 6 T standard cell area in FIG. 23, the metal pitch reaches about 30 nm, and uniform metal lines for routing and wider power rails are required. Thus, SAQP may be used in the formation process. In the 7.5 T standard cell area, the metal pitch is around 40 nm, and uniform metal lines for routing and wider power rails are required. Thus, SALELE may be used in the formation process. In the SRAM/IO area, the metal pitch is larger than 50 nm, and there are no clear layout rules for metal routing. Thus, SALELE may be used in the formation process. Therefore, by combining SAQP and SALELE, the 6 T standard cell areas, 7.5 T standard cell areas, and SRAM/IO areas that have different pitch requirements may be achieved over the same base.

In some embodiments, in the first area 100a, when the A-type first metal lines 150a with a larger width are formed for use as power lines of a standard unit, the B-type first metal lines 150b with a smaller width are used as device structure lines of the standard unit, the SAQP process may be used. That is, four device structure lines are formed between adjacent power lines in a standard unit, which is beneficial to reduce the occupied area of the standard unit and better improve the integration level of the standard unit.

Although the present disclosure is illustrated as above, the present disclosure is not limited thereto. Any person skilled in the art may make various changes and modifications without departing from the spirit and scope of the present disclosure. Therefore, the protection scope of the present disclosure should be subject to the scope defined by the claims.

What is claimed is:

1. A method for forming a semiconductor structure, comprising:
providing a base that includes a substrate and a target material layer on the substrate, forming a second core material layer over the base, and forming a first core material layer over the second core material layer, wherein the base includes a first area and a second area;
patterning the first core material layer and forming a plurality of first core layers separately in the first area, wherein the plurality of first core layers extend along a first direction and are arranged in parallel along a second direction, the plurality of first core layers have two adjacent first sub-core layers and a second sub-core layer arranged in an alternating manner, a width of the second sub-core layer is greater than a width of the first sub-core layer, and the first direction is perpendicular to the second direction;
forming a plurality of first spacers covering sidewalls of the plurality of first core layers, wherein first spacers of opposite sidewalls of adjacent first sub-core layers are in contact with each other to form an integrated structure;
removing the plurality of first core layers;
forming a first protective layer over the second core material layer in the second area, wherein the first protective layer is formed with a plurality of separate first protective layer openings extending along the first direction and arranged in parallel along the second direction;
patterning the second core material layer using the first protective layer and the plurality of first spacers as a mask, and forming a plurality of second core layers;
removing the first protective layer and the plurality of first spacers;
forming a plurality of second spacers that cover sidewalls of the plurality of second core layers;
removing second core layers of the plurality of second core layers in the first area and part of the plurality of second core layers in the second area; and
patterning the target material layer using the plurality of second spacers and remaining second core layers of the plurality of second core layers as a mask, and forming a plurality of first target structures in the first area and a plurality of second target structures in the second area, wherein first target structures of the plurality of first target structures corresponding to intervals between adjacent first sub-core layers of a plurality of first sub-core layers and a plurality of second sub-core layers are a plurality of first sub-target structures, first target structures of the plurality of first target structures between adjacent first sub-target structures of the plurality of first sub-target structures are a plurality of second sub-target structures, both the plurality of first target structures and the plurality of second target structures extend along the first direction, and a pitch of adjacent first target structures is smaller than or equal to a pitch of adjacent second target structures.

2. The method according to claim 1, wherein in a step of providing the base, the target material layer is a dielectric layer, the plurality of first target structures are a plurality of first trenches, the plurality of second target structures are a plurality of second trenches;
wherein in a step of patterning the target material layer using the plurality of second spacers and the remaining second core layers of the plurality of second core layers as the mask, the dielectric layer is patterned using the plurality of second spacers and the remaining second core layers of the plurality of second core layers as the mask, and the plurality of first trenches and the plurality of second trenches are formed in the dielectric layer; and
wherein after forming the plurality of first target structures in the first area and the plurality of second target structures in the second area, the method according to claim 1 further comprises:
forming a plurality of first metal lines in the plurality of first trenches and forming a plurality of second metal lines in the plurality of second trenches.

3. The method according to claim 1, wherein in a step of providing the base, the first area includes a logic device area, the second area includes a peripheral device area, and thickness of a gate oxide layer in the logic device area is smaller than thickness of a gate oxide layer in the peripheral device area.

4. The method according to claim 1, wherein a pitch of adjacent first target structures of the plurality of first target structures is 24 nm to 38 nm, and a pitch of adjacent second target structures of the plurality of second target structures is 38 nm to 200 nm.

5. The method according to claim 1, wherein in a step of patterning the first core material layer and forming the plurality of first core layers separately in the first area, a distance between adjacent first sub-core layers is equal to a preset width of the first sub-target structure, and a width of the second sub-core layer is equal to a sum of the preset width of the first sub-target structure and twice a preset width of the second spacer.

6. The method according to claim 1, wherein in a step of patterning the first core material layer and forming the plurality of first core layers separately in the first area, a width of the first sub-core layer is equal to a sum of a preset width of the second sub-target structure and twice a preset width of the second spacer, and a distance between adjacent first sub-core layer and second sub-core layer is equal to a sum of a preset width of the second sub-target structure, twice a preset width of the second spacer, and twice a preset width of the first spacer.

7. The method according to claim 1, wherein a step of forming the plurality of first spacers covering the sidewalls of the plurality of first core layers includes:
forming a first spacer material layer covering the sidewalls and a top of the plurality of first core layers and over the second core material layer, and portions of the first spacer material layer on opposite sidewalls of adjacent first sub-core layer contact each other; and
removing the first spacer material layer covering the top of the plurality of first core layers and over the second core material layer, and retaining the first spacer material layer covering the sidewalls of the plurality of first core layers as the plurality of first spacers.

8. The method according to claim 1, further comprising:
before forming the first protective layer over the second core material layer in the second area, forming a plurality of second protective layers separately over the second core material layer in the second area and covering the second core material layer and the plurality of first spacers in the first area;
changing an etching property of a portion of the second core material layer in the second area by using the plurality of second protective layers as a mask, and forming a plurality of third core material layers having an etching selectivity ratio with respect to the remaining second core material layers, wherein the remaining second core material layers are separately arranged in the second area and surrounded by the plurality of third core material layers in the second area;
wherein in a step of forming the first protective layer over the second core material layer in the second area, the first protective layer is separately formed over the second core material layer and the plurality of third core material layers;
wherein in a step of patterning the second core material layer using the first protective layer and the plurality of first spacers as a mask and forming the plurality of second core layers, a plurality of third core layers are formed corresponding to the third core material layer by pattering the plurality of third core material layers using the first protective layer as a mask;
in a step of forming the plurality of second spacers that cover the sidewalls of the plurality of second core layers, forming the plurality of second spacers that cover the sidewalls of the plurality of second core layers and sidewalls of the plurality of third core layers;
in a step of removing second core layers of the plurality of second core layers in the first area and the part of the plurality of second core layers in the second area, removing second core layers of the plurality of second core layers in the first area and the second area and retaining the plurality of third core layers; and
in a step of patterning the target material layer using the plurality of second spacers and the remaining second core layers of the plurality of second core layers as a mask, patterning the target material layer using the plurality of second spacers and the plurality of third core layers as a mask.

9. The method according to claim 8, further comprising:
in a step of forming the plurality of second protective layers separately over the second core material layer in the second area and covering the second core material layer and the plurality of first spacers in the first area, forming a plurality of second protective material layers covering the second core material layer and the plurality of first spacers;
patterning part of the plurality of second protective material layers in the second area, forming portions of the plurality of second protective material layers separately in the second area, and retaining part of the plurality of second protective material layers covering the plurality of second core material layers in the first area, wherein the portions of the plurality of second protective material layers in the second area and the part of the plurality of second protective material layers covering the plurality of second core material layers in the first area are used as the plurality of second protective layers collectively; and
after forming the plurality of third core material layers, removing the plurality of second protective layers.

10. The method according to claim 8, further comprising:
in a step of changing the etching property of the portion of the second core material layer in the second area by using the plurality of second protective layers as a mask, performing ion implantation in the portion of the second core material layer in the second area by using the plurality of second protective layers as a mask, and forming the plurality of third core material layers having the etching selectivity ratio with respect to the remaining second core material layer.

11. The method according to claim 10, wherein in a step of providing the base, a material of the second core material layer includes one or more of amorphous silicon, polycrystalline silicon, single crystal silicon, silicon oxide, advanced patterning film (APF) material, spin on carbon (SOC), and silicon carbide, and in a step of performing ion implantation in the portion of the second core material layer in the second area by using the plurality of second protective layers as a mask, ions implanted in the ion implantation include one or more of boron, phosphorus, arsenic, boron chloride, boron dichloride, and carbon.

12. The method according to claim 8, wherein in a step of changing the etching property of the portion of the second core material layer in the second area by using the plurality of second protective layers as a mask, a size of the remaining second core material layer along the second direction is 35 nm to 200 nm, and a pitch of the remaining second core material layer is 76 nm to 200 nm, a size of the plurality of third core material layers along the second direction is 35 nm to 200 nm, and a pitch of the plurality of third core material layers is 76 nm to 200 nm.

13. The method according to claim 1, further comprising:
in a step of forming the first protective layer over the second core material layer in the second area, forming the first protective material layer covering the second core material layer and the plurality of first spacers; and
patterning the first protective material layer, removing a part of the first protective material layer in the first area, removing a part of the first protective material layer with length extension along the first direction and with width extension along the second direction in the second area, and retaining a remaining part of the first protective material layer in the second area as the first protective layer.

14. The method according to claim 1, further comprising:
in a step of forming the plurality of second spacers that cover the sidewalls of the plurality of second core layers, forming a second spacer material layer covering the sidewalls and a top of the plurality of second core layers and a top of the base; and
removing a part of the second spacer material layer on the top of the plurality of second core layers and the top of the base, and retaining a part of the second spacer material layer on the sidewalls of the plurality of second core layers as the plurality of second spacers.

15. The method according to claim 1, further comprising:
in a step of providing the base, forming an etching stop layer between the first core material layer and the second core material layer;
before patterning the second core material layer using the first protective layer as a mask, patterning the etching stop layer using the plurality of first spacers as a mask, and forming a first pattern transfer layer;
in a step of patterning the second core material layer using the plurality of first spacers as a mask, patterning the second core material layer in the first area using the first pattern transfer layer as a mask, and forming the plurality of second core layers separately in the first area; and
after forming the plurality of second core layers, removing the first pattern transfer layer.

16. The method according to claim 1, wherein a wet etch process is used to remove the plurality of second core layers in the first area and a part of the plurality of second core layers in the second area.

17. The method according to claim 16, wherein in a step of using the wet etch process to remove the plurality of second core layers in the first area and the part of the plurality of second core layers in the second area, an etching solution of the wet etch process includes one or more of KOH solution, THMA solution, and SC1 solution.

18. The method according to claim 1, further comprising:
in a step of providing the base, forming a mask material layer between the target material layer and the second core material layer;
in a step of patterning the target material layer using the plurality of second spacers and the remaining second core layers of the plurality of second core layers as the mask, patterning the mask material layer using the plurality of second spacers and the remaining second core layers of the plurality of second core layers as the mask, forming a plurality of second pattern transfer layers;
patterning the target material layer using the plurality of second pattern transfer layers as a mask; and
after forming the plurality of first target structures and the plurality of second target structures, removing the plurality of second pattern transfer layers.

19. The method according to claim 18, further comprising:
after forming the plurality of second pattern transfer layers and before patterning the target material layer using the plurality of second pattern transfer layers as the mask, removing the plurality of second spacers and the remaining second core layers of the plurality of second core layers.

20. The method according to claim 1, wherein in a step of providing the base, a material of the first core material layer includes one or more of amorphous silicon, polycrystalline silicon, single crystal silicon, silicon oxide, advanced patterning film (APF) material, spin on carbon (SOC), and silicon carbide; in a step of forming the plurality of first spacers covering the sidewalls of the plurality of first core layers, a material of the plurality of first spacers includes one or more of titanium oxide, titanium nitride, silicon oxide, silicon nitride, silicon oxynitride, and silicon carbide; and in a step of forming the plurality of second spacers covering the sidewalls of the plurality of second core layers, a material of the plurality of second spacers includes one or more of titanium oxide, titanium nitride, silicon oxide, silicon nitride, silicon oxynitride, and silicon carbide.
